(19) United States
(12) Patent Application Publication
(10) Pub. No.: US 2007/0284735 A1
(43) Pub. Date: Dec. 13, 2007

(54) Semiconductor Device

(76) Inventors: Kazumasa Tanida, Kanagawa (JP); Shigo Higuchi, Kyoto (JP); Takuya Kadoguchi, Aichi (JP)

Correspondence Address: RABIN & Berdo, PC, 1101 14TH STREET, NW, SUITE 500, WASHINGTON, DC, 20005, US

(21) Appl. No.: 11/596,755

(22) PCT Filed: Oct. 6, 2005
(86) PCT No.: PCT/JP05/18556

§ 371 Date: Nov. 16, 2006

(30) Foreign Application Priority Data
Oct. 14, 2004 (JP) 2004-300532

(51) Int. Cl. H01L 23/12

(52) U.S. Cl. 257/731; 257/E23.003

(57) ABSTRACT

A semiconductor device (1, 1A, 21, 31, 41, 51) provided with a first semiconductor chip (3) having a first functional surface (3F) formed with a first functional element (3a), a protective resin layer (12) provided on the first functional surface, and an external connection terminal (10, 19, 52) provided on a peripheral portion of the first functional surface for external electrical connection, the external connection terminal having a bottom surface (10B, 19BB) exposed from a bottom surface (12B) of the protective resin layer facing away from the first functional surface and a side surface (10S, 19BS) exposed from a side surface (12S) of the protective resin layer.

### TECHNICAL FIELD

The present invention relates to a semiconductor device having substantially the same size as a semiconductor chip.

### BACKGROUND ART

In recent years, semiconductor devices have been required to have a smaller size and a higher mounting density. The semiconductor devices satisfying such requirements include a chip size package (CSP; disclosed in the following Patent Publication 1) and a multi-chip module (MCM; disclosed in the following Patent Publication 2).

FIG. 12 is a schematic sectional view illustrating a construction of a prior art semiconductor device having a chip size package structure.

The semiconductor device 71 includes a semiconductor chip 72. The semiconductor chip 72 includes a functional element 72a formed in one surface thereof, and an insulation film 73 covering the functional element 72a. The insulation film 73 has openings 73a through which electrodes of the functional element 72a are exposed.

Rewirings 74 arranged in a predetermined pattern are provided on the insulation film 73. The rewirings 74 are respectively connected to the electrodes of the functional element 72a through the openings 73a of the insulation film 73.

A protective resin layer 77 is provided on the one surface of the semiconductor chip 72 as covering the insulation film 73 and the rewirings 74. Side surfaces of the semiconductor chip 72 are flush with side surfaces of the protective resin layer 77, so that the semiconductor device 71 has a generally rectangular parallelepiped outer shape. Therefore, the semiconductor device 71 has substantially the same size as the semiconductor chip 72 as seen perpendicularly to the semiconductor chip 72. Columnar external connection terminals 75 project from predetermined portions of the rewirings 74 as extending through the protective resin layer 77. Solder balls 76 as external connection members are respectively bonded to distal ends of the external connection terminals 75.

The semiconductor device 71 is mountable on amounting board by bonding the solder balls 76 to electrode pads provided on the mounting board.

FIG. 13 is a schematic sectional view illustrating a construction of a prior art semiconductor device having a multi-chip module structure.

The semiconductor device 81 includes a wiring board 82, a semiconductor chip 83 stacked on the wiring board 82, and a semiconductor chip 84 stacked on the semiconductor chip 83. The semiconductor chips 83, 84 each include a functional element 83a, 84a formed in one surface thereof. The semiconductor chip 83 is bonded onto the wiring board 82 in a so-called face-up state in which the surface thereof formed with the functional element 83a faces away from the wiring board 82.

The semiconductor chip 84 is bonded onto the semiconductor chip 83 in a face-up state in which the functional element 84a faces away from the semiconductor chip 83. An interlayer sealing material 86 is interposed between the semiconductor chip 83 and the semiconductor chip 84.

The semiconductor chip 83 has a greater size than the semiconductor chip 84 as seen perpendicularly to the surfaces formed with the functional elements 83a, 84a, so that the surface of the semiconductor chip 83 on which the semiconductor chip 84 is bonded has a peripheral region which is not opposed to the semiconductor chip 84. Electrode pads 83b connected to the functional element 83a are provided on the peripheral region of the semiconductor chip 83. Electrode pads 84b connected to the functional element 84a are provided on a peripheral portion of the surface of the semiconductor chip 84 formed with the functional element 84a.

The wiring board 82 has a greater size than the semiconductor chip 83 as seen perpendicularly to the wiring board 82, so that the surface of the wiring board 82 on which the semiconductor chip 83 is bonded has a peripheral region which is not opposed to the semiconductor chip 83. Electrode pads not shown are provided on the peripheral region of the wiring board 82, and respectively connected to the electrode pads 83b, 84b via bonding wires 87, 88.

The semiconductor chips 83, 84 and the bonding wires 87, 88 are sealed in a mold resin 89.

Solder balls 85 as external connection members are provided on a surface of the wiring board 82 opposite from the surface on which the semiconductor chip 83 is bonded. The electrode pads of the wiring board 82 connected to the bonding wires 87, 88 are connected to the solder balls 85 by rewirings on the surface of the wiring board 82 and/or in the wiring board 82.

The semiconductor device 81 is mountable on amounting board by bonding the solder balls 85 to electrode pads provided on the mounting board.

Patent Publication 1: Japanese Unexamined Patent Publication No. 2002-118224

Patent Publication 2: Japanese Unexamined Patent Publication No. 2000-270721

### DISCLOSURE OF THE INVENTION

### Problems to be solved by the invention

However, in the semiconductor device 71 shown in FIG. 12, the solder balls 76 are two-dimensionally arranged (in an area array) on a surface (hereinafter referred to as “bottom surface”) 71a of the protective resin layer 77 opposite from the semiconductor chip 72. Similarly, in the semiconductor device 81 of FIG. 13, the solder balls 85 are two-dimensionally arranged (in an area array) on a surface (hereinafter referred to as “bottom surface”) 81a of the wiring board 82 opposite from the semiconductor chips 83, 84.

Therefore, it is difficult to check whether the solder balls 76, 85 provided on an inner region of the bottom surface 71a, 81a are properly bonded to the electrode pads on the mounting board after the semiconductor device 71, 81 is mounted on the mounting board.

Where the solder balls 76, 85 are provided, voids are liable to be introduced in the solder balls 76, 85 in formation of the solder balls. The solder balls 76, 85 having the voids are liable to cause a connection failure with respect to the mounting board.

In the case of the semiconductor device 81 shown in FIG. 13, the wiring board 82 is required to have a greater size than the semiconductor chip 83 in order to provide the region for the connection to the bonding wires 87, 88. Therefore, the semiconductor device 81 (package) has a greater size, particularly, as seen perpendicularly to the wiring board 82, than the semiconductor chip 83, 84. Therefore, the semiconductor device 81 requires a greater mount area on the mounting board.

Where a plurality of semiconductor chips 72 are to be mounted on the mounting board by way of the semiconductor devices 71 each shown in FIG. 12, the semiconductor devices 71 should be arranged laterally on the mounting board, thereby requiring a greater mount area.

It is an object of the present invention to provide a semiconductor device which ensures that, when the semiconductor device is bonded to a mounting board, the bonding state of the semiconductor device on the mounting board can be easily checked.

It is another object of the present invention to provide a semiconductor device which has a chip size and an improved external connection reliability.

It is further another object of the present invention to provide a semiconductor device which has a multi-chip module structure and requires a reduced mount area.

Means for Solving the Problems

A semiconductor device according to the present invention comprises a first semiconductor chip having a first functional surface formed with a first functional element, a protective resin layer provided on the first functional surface, and an external connection terminal provided on a peripheral portion of the first functional surface for external electrical connection, the external connection terminal having a bottom surface exposed from a bottom surface of the protective resin layer facing away from the first functional surface and a side surface exposed from a side surface of the protective resin layer.

According to the present invention, the external connection terminal has the exposed surface on the side surface of the protective resin layer. Therefore, when the semiconductor device is mounted on a mounting board, a connection between the external connection terminal and an electrode pad on the mounting board can be easily directly viewed. Thus, the connection state (bonding state) of the semiconductor device on the mounting board can be easily checked.

The semiconductor device is connected to the mounting board, for example, by a solder. The solder may be preliminarily provided in a film form on the electrode pad on the mounting board by applying a solder paste (and further melting and solidifying the solder paste). Since voids are less likely to be introduced into the solder in such a form, the external connection reliability is improved.

The external connection terminal of the semiconductor device is connected to the mounting board not only via the exposed bottom surface thereof but also via the exposed side surface thereof, so that a higher bonding strength and a higher bonding reliability can be ensured.

The external connection terminal may be electrically connected to the first semiconductor chip (first functional element). In this case, an insulation film having an opening through which an electrode of the first functional element is exposed may be provided on the first functional surface, and the external connection terminal may be connected to a rewiring connected to the electrode of the first functional element through the opening of the insulation film.

The inventive semiconductor device may further comprise a heat-sink terminal provided in a center region of the first functional surface located inwardly of the peripheral portion formed with the external connection terminal and having a surface exposed from the bottom surface of the protective resin layer.

With this arrangement, heat generated by the first semiconductor chip is dissipated via the heat-sink terminal. Since the heat-sink terminal has the exposed surface on the bottom surface of the protective resin layer, the heat dissipation can be efficiently achieved. The size of the heat-sink terminal can be great to the extent that the heat-sink terminal does not contact the external connection terminal provided on the peripheral portion of the first functional surface. Thus, the heat dissipation efficiency of the heat-sink terminal is improved.

The heat-sink terminal may be electrically connected to the first functional element through the opening formed in the insulation film, for example, by a rewiring. In this case, the heat-sink terminal may be a power source interconnection for supplying a voltage to the first functional element or a grounding interconnection for grounding the first functional element. In this case, the operation of the first semiconductor chip (functional element) is stabilized.

The heat-sink terminal may be electrically unconnected to the first functional element.

The heat-sink terminal may be formed of, for example, the same material as the external connection terminal. In this case, the external connection terminal and the heat-sink terminal can be simultaneously formed, for example, by electrolytic plating.

The inventive semiconductor device may further comprise a second semiconductor chip having a second functional surface formed with a second functional element and connected to the first semiconductor chip with the second functional surface thereof being opposed to the first functional surface, the second semiconductor chip having a smaller size than the first semiconductor chip as seen in plan perpendicularly to the first functional surface.

The inventive semiconductor device can be mounted on the mounting board in such a state that the bottom surface of the protective resin layer from which the external connection terminal is exposed is opposed to the mounting board. Thus, the first semiconductor chip and the second semiconductor chip are stacked on the mounting board. Therefore, the semiconductor device requires a reduced mount area as compared with a case where the first semiconductor chip and the second semiconductor chip are separately mounted in juxtaposition on the mounting board.

Here, the second semiconductor chip has a size such as to be accommodated in a region of the first semiconductor chip as seen in plan perpendicularly to the first functional surface. Therefore, the mount area can be reduced to a level which is equivalent to the size of the first semiconductor chip as seen perpendicularly to the first functional element, though the semiconductor device is a multi-chip module.

The protective resin layer may have a concave recess provided in the side surface thereof. In this case, the external connection terminal may include a concave portion provided on an interior surface of the concave recess as having a shape conforming to the interior shape of the concave recess.

With this arrangement, the concave portion is provided on the interior surface of the concave recess provided in the side surface of the protective resin layer. Therefore, the exposed surface (the surface of the concave portion) of the external connection terminal is curved (bowed or bent) on the side surface of the protective resin layer and, hence, has a greater surface area as compared with a case where the exposed surface of the external connection terminal is flat. Thus, the bonding area (soldering area) of the external connection terminal on the mounting board is increased to increase the bonding strength.

The first semiconductor chip may have a side surface which is substantially flush with the side surface of the protective resin layer.

With this arrangement, the protective resin layer protects the structure on the first functional surface, and reduces the mount area of the semiconductor device.

The semiconductor device may be produced from a semiconductor substrate (e.g., a semiconductor wafer) formed with a plurality of first semiconductor chips. In this case, the semiconductor substrate may have an columnar electrode provided in a region spanned between adjacent first semiconductor chips, as seen perpendicularly to the semiconductor substrate, as extending thickness wise through the protective resin layer (perpendicularly to the semiconductor substrate) and electrically connected to functional elements of the adjacent first semiconductor chips.

By cutting the semiconductor substrate along a boundary between the adjacent first semiconductor chips, the inventive semiconductor device is produced. The columnar electrode thus cut serves as the external connection terminal. In this case, the exposed surface of the external connection terminal present on the side surface of the protective resin layer is flush with the side surface of the protective resin layer.

Where the external connection terminal includes the concave portion provided in the concave recess, the semiconductor substrate formed with the plurality of first semiconductor chips has a through-hole formed in the region spanned between the adjacent first semiconductor chips as seen perpendicularly to the semiconductor substrate, the through-hole extending thickness wise through the protective resin layer. In this case, an electrically conductive film is provided on an interior surface of the through-hole as extending thickness wise through the protective resin layer (perpendicularly to the semiconductor substrate) and electrically connected to the functional elements of the adjacent first semiconductor chips, so that the through-hole is not completely filled.

By cutting the semiconductor substrate along the boundary between the adjacent first semiconductor chips, the semiconductor device is produced in which the electrically conductive film serves as the external connection terminal with the concave portion provided in the concave recess of the cut through-hole.

In this case, the through-hole is not completely filled with the electrically conductive film. Therefore, this production method can reduce abrasion of a tool such as a dicing blade or a cutting die to be used for cutting the semiconductor substrate along the boundary between the adjacent first semiconductor chips as compared with the production method in which the semiconductor device is produced from the semiconductor substrate formed with the columnar electrode.

The external connection terminal may include a main portion embedded in the protective resin layer, and a coating film provided on a surface of the main portion as having the exposed bottom surface and the exposed side surface and composed of a material having a higher solder wettability than the main portion.

With this arrangement, the coating film ensures an excellent solder wettability even if the main portion does not have a sufficient solder wettability (even if the main portion is composed of a material susceptible to formation of a surface oxide and has a poorer solder wettability due to the oxide). Thus, the connection reliability of the external connection terminal on the mounting board is improved. The coating film may be composed of, for example, a material less susceptible to oxidation than the main portion.

The foregoing and other objects, features and effects of the present invention will become more apparent from the following description of embodiments with reference to the attached drawings.

### BRIEF DESCRIPTION OF THE DRAWINGS

FIG. 1 is a schematic sectional view illustrating a construction of a semiconductor device according to a first embodiment of the present invention;

FIG. 2 is a schematic bottom view of the semiconductor device shown in FIG. 1;

FIG. 3A is a schematic bottom view for explaining a production method for the semiconductor device shown in FIGS. 1 and 2;

FIG. 3B is a schematic bottom view for explaining another production method for the semiconductor device shown in FIGS. 1 and 2;

FIG. 3C is a schematic sectional view for explaining a production method for a semiconductor device including an external connection terminal having a main portion and a coating film;

FIG. 3D is a schematic sectional view for explaining the production method for the semiconductor device including the external connection terminal having the main portion and the coating film;

FIG. 4 is a schematic sectional view illustrating a construction of a semiconductor device according to a second embodiment of the present invention;

FIG. 5 is a schematic bottom view of the semiconductor device shown in FIG. 4;

FIG. 6 is a schematic sectional view illustrating a construction of a semiconductor device according to a third embodiment of the present invention;

FIG. 7 is a schematic sectional view illustrating a construction of a semiconductor device according to a modification of the semiconductor device shown in FIG. 6;

FIG. 8 is a schematic sectional view illustrating a construction of a semiconductor device according to a fourth embodiment of the present invention;

FIG. 9 is a schematic bottom view of the semiconductor device shown in FIG. 8;

FIG. 10 is a schematic perspective view of the semiconductor device shown in FIGS. 8 and 9, illustrating a portion of the semiconductor device around an external connection terminal;

FIG. 11 is a schematic bottom view for explaining a production method for the semiconductor device shown in FIGS. 8 and 9;

FIG. 12 is a schematic sectional view illustrating a construction of a prior art semiconductor device having a chip size package structure; and

FIG. 13 is a schematic sectional view illustrating a construction of a prior art semiconductor device having a multi-chip module structure.

### BEST MODE FOR IMPLEMENTING THE INVENTION

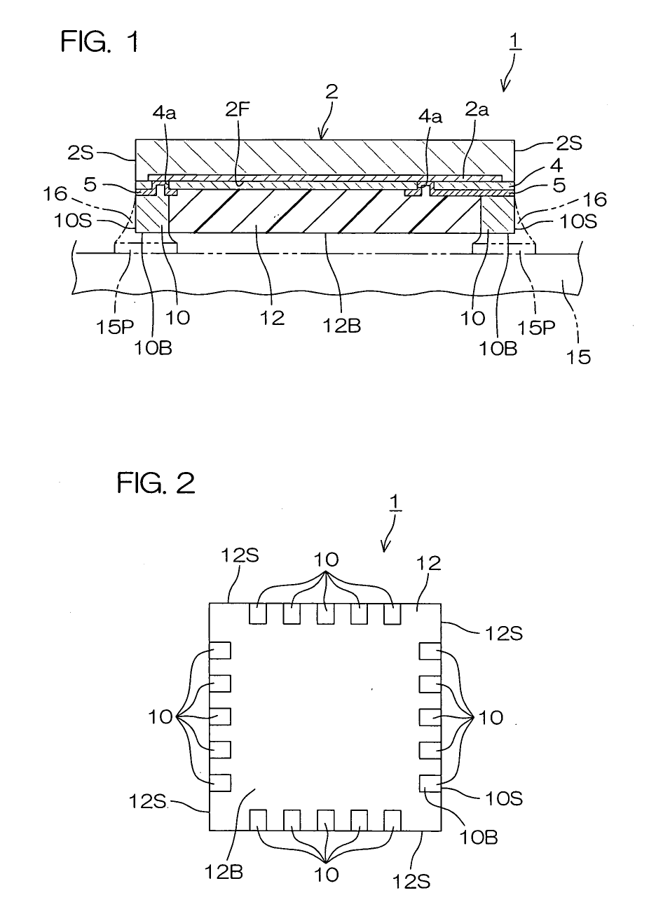

FIG. 1 is a schematic sectional view illustrating a construction of a semiconductor device according to a first embodiment of the present invention, and FIG. 2 is a schematic bottom view of the semiconductor device. The semiconductor device 1 is a so-called chip size package (CSP), and includes a semiconductor chip 2.

The semiconductor chip 2 includes a semiconductor element 2a provided in one surface (functional surface 2F) thereof. The functional element 2a may be, for example, a transistor. An insulation film 4 is provided on the functional surface 2F as covering the functional element 2a. The insulation film 4 has openings 4a through which electrodes of the functional element 2a are exposed.

Rewirings 5 respectively electrically connected to the electrodes of the functional element 2a through the openings 4a are provided on the insulation film 4. Further, a protective resin layer 12 is provided over the insulation film 4 as covering the rewirings 5. Side surfaces 2S of the semiconductor chip 2 are substantially flush with side surfaces 12S of the protective resin layer 12, so that the semiconductor device 1 has a generally rectangular parallelepiped outer shape.

A plurality of external connection terminals 10 of a metal are provided in a peripheral portion of the protective resin layer 12 (semiconductor device 1) as extending thickness wise through the protective resin layer 12 from the rewirings 5. Each opposed pair of external connection terminals 10 on two parallel side surfaces 12S are disposed at substantially the same distance from a side surface 12S perpendicular to the two parallel side surfaces 12S.

The external connection terminals 10 each have a rectangular columnar shape. The external connection terminals 10 each have a side surface 10S exposed from the side surface 12S of the protective resin layer 12, and a bottom surface 10B exposed from a bottom surface 12B of the protective resin layer 12. The exposed side surface 10S and the exposed bottom surface 10B are substantially flush with the side surface 12S and the bottom surface 12B, respectively.

The semiconductor device 1 is mountable on a mounting board 15 via the exposed side surfaces 10S and the exposed bottom surfaces 10B of the respective external connection terminals 10. In this case, the exposed side surfaces 10S and the exposed bottom surfaces 10B are connected to electrode pads 15P provided on a surface of the mounting board 15 by a solder 16 (in FIG. 1, the mounting board 15, the electrode pads 15P and the solder 16 are illustrated by two-dot-and-dash lines).

Here, the external connection terminals 10 are provided in the peripheral portion of the protective resin layer 12 (semiconductor device 1), but not in an inward region of the protective resin layer 12. Further, the external connection terminals 10 each have the exposed side surface 10S on the side surface 12S of the protective resin layer 12. Therefore, portions of the external connection terminals 10 connected to the mounting board 15 can be easily directly viewed. Thus, the connection state can be easily checked.

The solder 16 may be preliminarily provided in a film form on the electrode pads 15P on the mounting board 15 by applying a solder paste (and further melting and solidifying the solder paste). Since voids are less likely to be introduced into the solder 16 in such a form, the semiconductor device 1 has an improved external connection reliability.

Further, the external connection terminals 10 are bonded to the mounting board 15 by solder portions 16 present between the electrode pads 15P and the exposed bottom surfaces 10B as well as solder portions 16 (solder fillets) present between the electrode pads 15P and the exposed side surfaces 10S. Therefore, the bonding strength with respect to the mounting board 15 is increased.

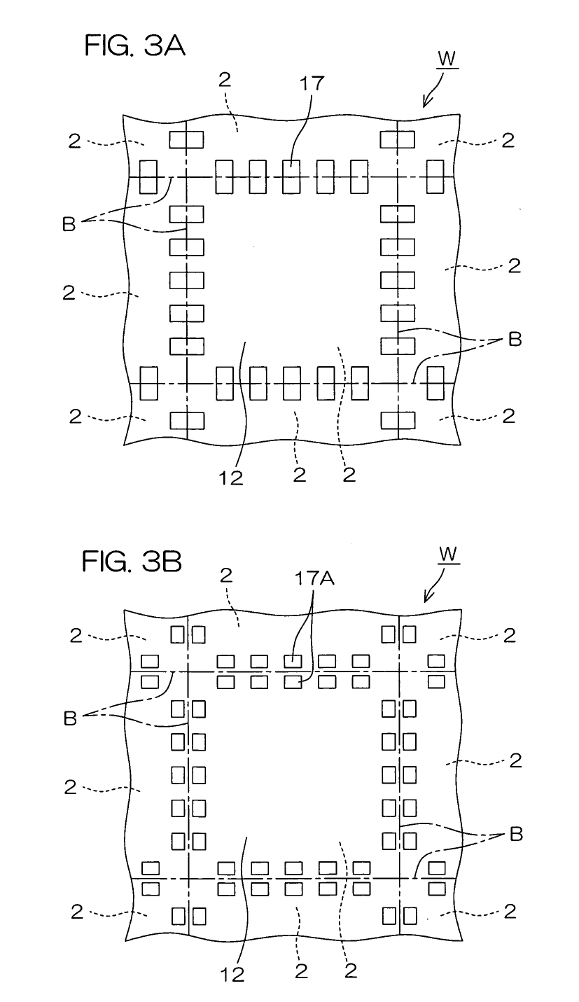

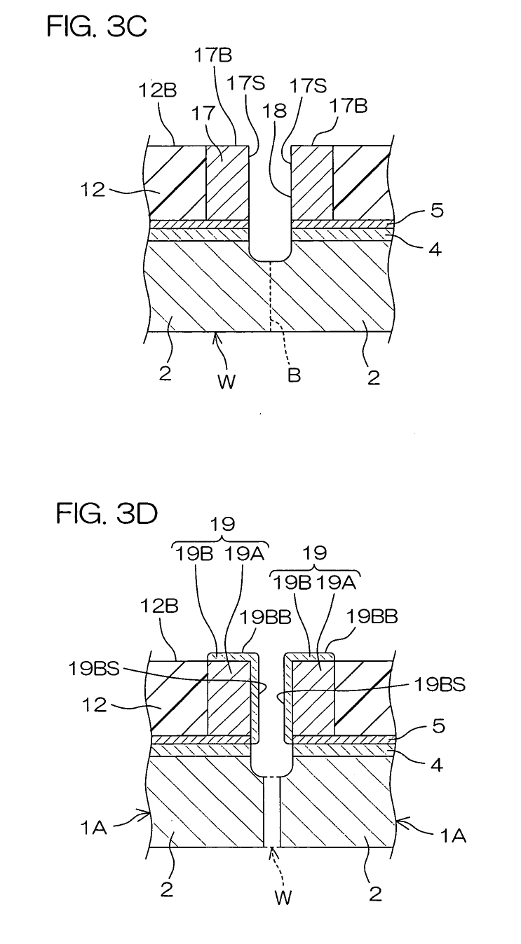

FIG. 3A is a schematic bottom view for explaining a production method for the semiconductor device 1. The semiconductor device 1 is produced from a semiconductor substrate formed with a plurality of semiconductor chips 2. In FIG. 3A, a semiconductor wafer (hereinafter referred to simply as “wafer”) W as such a semiconductor substrate is shown.

As seen perpendicularly to the wafer W, columnar electrodes 17 are provided in regions spanned between adjacent semiconductor chips 2 in the wafer W, as extending thickness wise through a protective resin layer 12 (perpendicularly to the wafer W), the columnar electrode 17 being electrically connecting functional elements 2a of the adjacent semiconductor chips 2. The columnar electrodes 17 are formed, for example, by electrolytic plating.

The semiconductor device 1 is produced by cutting the wafer W along boundaries B (indicated by a one-dot-and-dash line in FIG. 3A) between the adjacent semiconductor chips 2 by a dicing blade or a cutting die. The columnar electrodes 17 thus cut serve as the external connection terminals 10. Therefore, the exposed side surfaces 10S of the external connection terminals 10 are flat and flush with the side surfaces 12S of the protective resin layer 12 (see FIG. 2).

Where a cutting allowance of the wafer W to be cut by the dicing blade is great, plural pairs of columnar electrodes 17A may be provided on the semiconductor chips 2 as spaced perpendicularly to the boundaries B on opposite sides of the boundaries B as shown in FIG. 3B. In this case, a distance between the columnar electrodes 17A in each pair is shorter than the cutting allowance for the dicing blade. The wafer W is cut so that portions of the wafer W between the columnar electrodes 17A in the respective pairs are accommodated in the cutting allowance. Thus, the semiconductor device 1 is provided, which includes the external connection terminals 10 defined by the columnar electrodes 17A and each having the side surface 10S exposed from the side surface 12S of the protective resin layer 12 defined by a cut surface.

Coating films of a material having a higher solder wettability than the external connection terminals 10 may be provided on the exposed side surfaces 10S and the exposed bottom surfaces 10B of the external connection terminals 10. That is, the external connection terminals may each include a main portion corresponding to the external connection terminal 10 and a coating film provided on a surface of the main portion.

In this case, the coating film ensures an excellent solder wettability even if the main portion (corresponding to the external connection terminal 10) is composed of a material (e.g., copper) susceptible to formation of a surface oxide and is liable to have an insufficient solder wettability due to the oxide. Therefore, the connection reliability of the semiconductor device 1 on the mounting board 15 is improved.

FIGS. 3C and 3D are schematic sectional views for explaining a production method for the semiconductor device including the external connection terminals each having the main portion and the coating film.

First, a wafer W formed with a plurality of semiconductor chips 2 as shown in FIG. 3A or 3B is prepared.

Then, grooves 18 are formed in the wafer W along boundaries B between adjacent semiconductor chips 2, for example, by a dicing blade so as to extend thickness wise through columnar electrodes 17, a protective resin layer 12, a rewiring 5 and an insulation film 4 from a bottom surface 12B of the protective resin layer 12 to a surface portion of the wafer W as shown in FIG. 3C. In this state, the columnar electrodes 17 each have a surface (cut surface) 17S exposed to the groove 18 and a surface 17B exposed from the bottom surface 12B of the protective resin layer 12.

In turn, the wafer W is immersed in a plating liquid, whereby coating films 19B each including a nickel (Ni) layer and a gold (Au) layer in this order are formed on the exposed surfaces 17S, 17B, for example, by electroless plating.

Thereafter, the wafer W is cut along the boundaries B between the adjacent semiconductor chips 2, for example, by a dicing blade having a smaller thickness than the dicing blade used for the formation of the grooves 18 (see FIG. 3D). At this time, the dicing blade is inserted into the groove 18 so as not to contact the coating films 19B. Thus, a semiconductor device 1A is provided which includes external connection terminals 19 each having a main portion 19A provided by cutting the columnar electrodes 17 and the coating film 19B formed on a surface of the main portion 19A.

The wafer W may be cut by the dicing blade from a surface thereof opposite from the surface formed with the grooves 18.

In this production method, the coating films 19B can be simultaneously formed on the plurality of semiconductor chips 2 by performing the electroless plating without completely cutting the wafer W.

The coating films 19 Beach have a bottom surface 19BB exposed from the bottom surface 12B of the protective resin layer 12, and a side surface 19BS exposed from the side surface 12S of the protective resin layer 12. The coating film 19B slightly protrudes from the surface of the main portion 19A, but the exposed side surface 19BS is substantially flush with the side surface 2S of the semiconductor chip 2.

The semiconductor device 1A is mountable on a mounting board 15 via the exposed side surfaces 19BS and the exposed bottom surfaces 19BB of the external connection terminals 19 with the use of a solder. Even if the main portions 19A each have an insufficient solder wettability (or is liable to have an insufficient solder wettability), the coating films 19B ensure an excellent solder wettability. Therefore, the connection reliability of the semiconductor device 1A on the mounting board 15 is improved.

In this production method, the wafer W is immersed in the plating liquid for the electroless plating but, instead, the wafer W may be dipped in a solder bath (solder melt) for forming solder coating films on the exposed surfaces 17S, 17B. In this case, a semiconductor device is provided which includes external connection terminals each including a solder coating film formed on the surface of the main portion 19A.

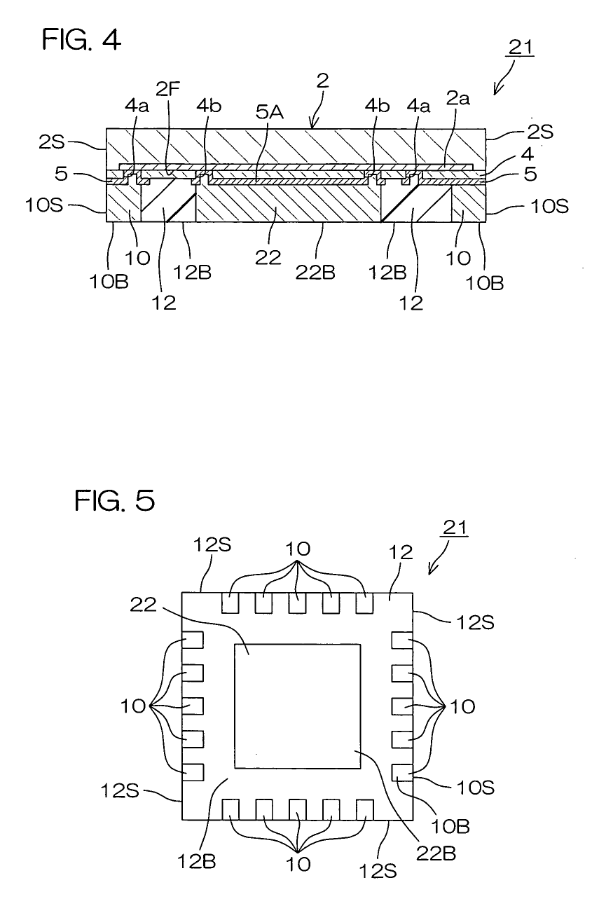

FIG. 4 is a schematic sectional view of a semiconductor device according to a second embodiment of the present invention, and FIG. 5 is a schematic bottom view of the semiconductor device. In FIGS. 4 and 5, components corresponding to those shown in FIGS. 1 and 2 will be denoted by the same reference characters as in FIGS. 1 and 2.

The semiconductor device 21 includes a heat-sink terminal 22 provided in a center portion of the semiconductor chip 2 as seen in plan perpendicularly to the bottom surface 12B. The heat-sink terminal 22 projects from a rewiring 5A provided on the insulation film 4. The insulation film 4 has openings 4b through which electrodes of the functional element 2a are exposed. The rewiring 5A is electrically connected to the electrodes of the functional element 2a through the openings 4b. Therefore, the heat-sink terminal 22 is electrically connected to the functional element 2a.

The heat-sink terminal 22 extends thickness wise through the protective resin layer 12, and has a surface 22B exposed from the bottom surface 12B of the protective re sin layer 12. The exposed surface 22B is substantially flush with the bottom surface 12B.

The semiconductor device 21 is mountable on a mounting board via the exposed bottom surfaces 10B and the exposed side surfaces 10S of the external connection terminals 10 and the exposed surface 22B of the heat-sink terminal 22. The mounting board may include an electrode pad for the heat-sink terminal 22 in addition to the electrode pads for the external connection terminals 10. In this case, the electrode pads provided on the surface of the mounting board may be connected to the exposed side surfaces 10S, the exposed bottom surfaces 10B and the exposed surface 22B by a solder.

The size of the exposed surface 22B is great to the extent that short circuit by the solder between the exposed surface 22B and the exposed bottom and side surfaces 10B, 10S does not occur in the mounting. The heat-sink terminal 22 is provided in an inward region of the protective resin layer 12, so that a portion of the exposed surface 22B bonded to the electrode pad of the mounting board cannot be directly viewed. However, the bonding is achieved easily and assuredly, because the exposed surface 22B has a great size.

In the semiconductor device 21, heat generated by the semiconductor chip 2 is dissipated via the heat-sink terminal 22. Therefore, the semiconductor device 21 has a higher heat dissipation efficiency. That is, the heat dissipation efficiency of the semiconductor device 21 is improved by increasing the size of the exposed surface 22B.

The heat-sink terminal 22 may be a power source interconnection for supplying a voltage to the functional element 2a or a grounding interconnection for grounding the functional element 2a. In this case, the operation of the semiconductor chip 2 (functional element 2a) is stabilized.

The heat-sink terminal 22 may be composed of, for example, the same material as the external connection terminals 10. In this case, the external connection terminals 10 and the heat-sink terminal 22 can be simultaneously formed, for example, by electrolytic plating.

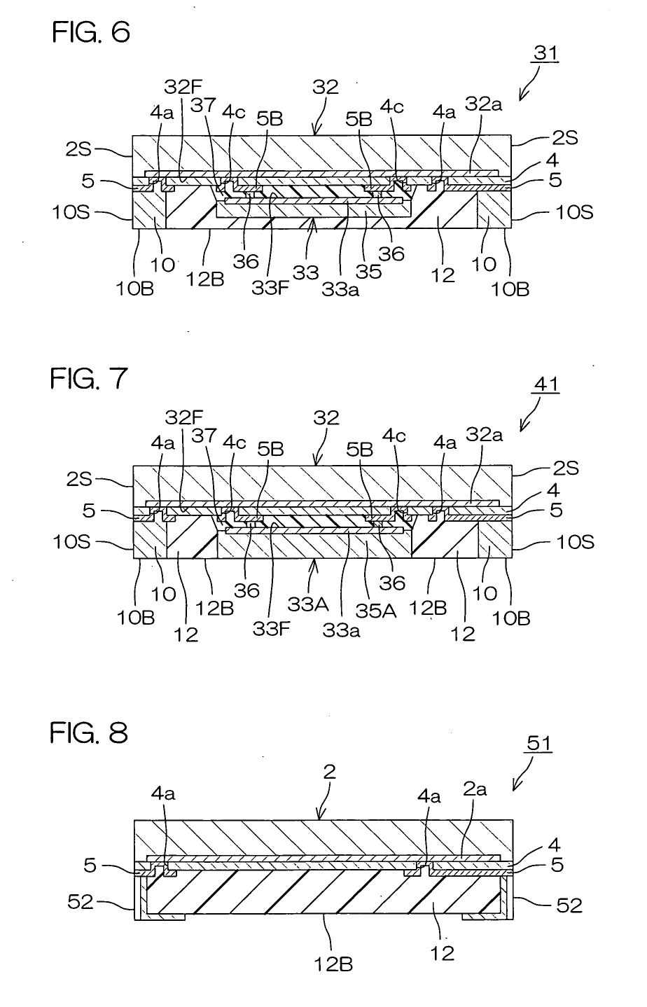

FIG. 6 is a schematic sectional view illustrating a construction of a semiconductor device according to a third embodiment of the present invention. In FIG. 6, components corresponding to those shown in FIGS. 1 and 2 will be denoted by the same reference characters as in FIGS. 1 and 2. The semiconductor device 31 is a multi-chip module including a first semiconductor chip 32 and a second semiconductor chip 33.

The first semiconductor chip 32 includes a first functional element 32a formed in one surface (first functional surface 32F) thereof. An insulation film 4 is provided over the first functional surface 32F as covering the functional element 32a. The insulation film 4 has openings 4a, 4c through which electrodes of the functional element 32a are exposed. Rewirings 5B respectively electrically connected to the electrodes of the functional elements 32a through the openings 4c are provided on the insulation film 4.

The second semiconductor chip 33 includes a second functional element 33a formed in one surface (second functional surface 33F) thereof. The second semiconductor chip 33 is spaced a predetermined distance from the insulation film 4 and bonded to the first semiconductor chip 32 with the second functional surface 33F thereof being opposed to the first functional surface 32F of the first semiconductor chip 32 (insulation film 4).

Electrodes of the second functional element 33a are respectively electrically connected to the rewirings 5B via connection members 36. Thus, the first functional element 32a and the second functional element 33a are electrically connected to each other.

A space between the insulation film 4 and the second semiconductor chip 33 is filled with an under-fill layer 37.

The second semiconductor chip 33 has a size such as to be accommodated on the first semiconductor chip 32 as seen in plan perpendicularly to the first functional surface 32F, and is disposed on a center portion of the first semiconductor chip 32. External connection terminals 10 are disposed on lateral sides of the second semiconductor chip 33 as surrounding the second semiconductor chip 33. The second semiconductor chip 33 is sealed in a protective resin layer 12, and has no surface exposed from the protective resin layer 12.

The size of the second semiconductor chip 33 is such that the second semiconductor chip 33 is accommodated in a region of the first semiconductor chip 32 as seen in plan perpendicularly to the first functional surface 32F. Therefore, the semiconductor device 31 has a mount area reduced to a level equivalent to the size of the first semiconductor chip 32 as seen perpendicularly to the first functional surface 32F, though the semiconductor device 31 is a multi-chip module.

FIG. 7 is a schematic sectional view illustrating a construction of a semiconductor device according to a modification of the semiconductor device 31. In FIG. 7, components corresponding to those shown in FIG. 6 will be denoted by the same reference characters as in FIG. 6.

The semiconductor device 41 includes a second semiconductor chip 33A instead of the second semiconductor chip 33. The second semiconductor chip 33A has a greater thickness than the second semiconductor chip 33.

A rear surface of the second semiconductor chip 33A (opposite from the second functional surface 33F) is exposed from the protective resin layer 12, and is substantially flush with the bottom surface 12B. Thus, the heat dissipation efficiency of the second semiconductor chip 33A is improved.

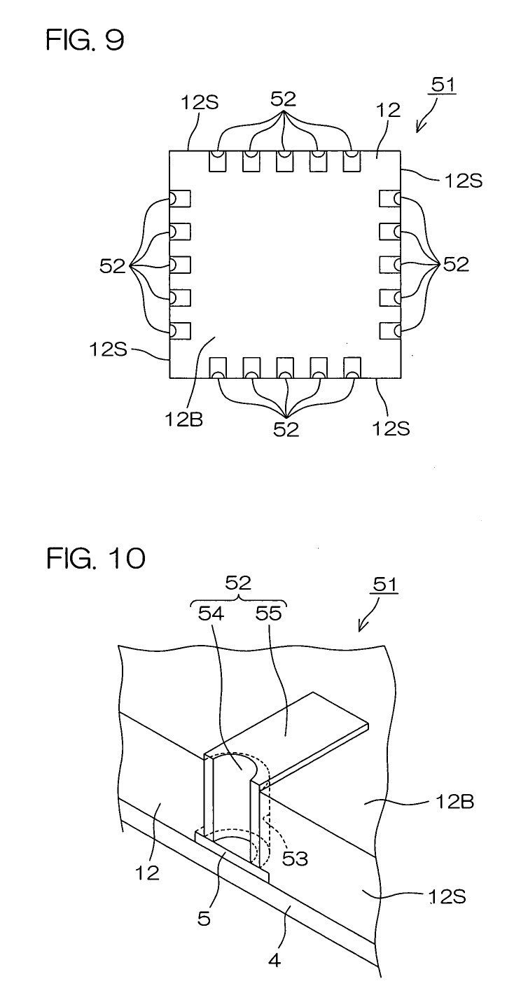

FIG. 8 is a schematic sectional view illustrating a construction of a semiconductor device according to a fourth embodiment of the present invention, and FIG. 9 is a schematic bottom view of the semiconductor device. In FIG. 8, components corresponding to those shown in FIGS. 1 and 2 will be denoted by the same reference characters as in FIGS. 1 and 2.

The semiconductor device 51 includes film-shaped external connection terminals 52 instead of the columnar external connection terminals 10 of the semiconductor device 1 shown in FIG. 1.

FIG. 10 is a schematic perspective view of the semiconductor device 51, illustrating a portion of the semiconductor device 51 around the external connection terminal 52.

The protective resin layer 12 has semicylindrical grooves 53a formed in the side surfaces 12S thereof as extending thickness wise through the protective resin layer 12.

The external connection terminals 52 each include a concave portion 54 provided on an interior surface of the groove 53, and a flat portion 55 provided on the bottom surface 12B of the protective resin layer 12 around the groove 53. The concave portion 54 and the flat portion 55 are unitarily provided. The concave portion 54 is electrically connected to the rewiring 5, and has a curved surface (exposed surface) or a semicylindrical surface conforming to the interior surface of the semicylindrical groove 53. The flat portion 55 extends inwardly from an edge of the concave portion 54 on the bottom surface 12B.

Referring to FIGS. 8 to 10, the semiconductor device 51 is mountable on a mounting board via the concave portions 54 and the flat portions 55 of the external connection terminals 52. In this case, the concave portions 54 and the flat portions 55 are connected by a solder to electrode pads provided on a surface of the mounting board.

The concave portions 54 each have the curved surface and, therefore, have a greater surface area than the flat exposed side surfaces 10S of the external connection terminals 10. Therefore, the bonding area (soldering area) with respect to the mounting board is increased, thereby increasing the bonding strength.

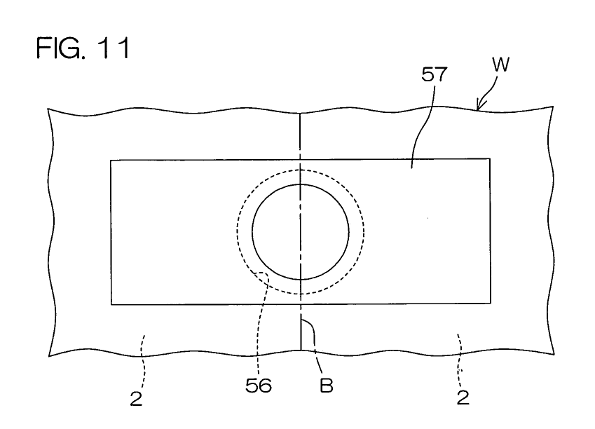

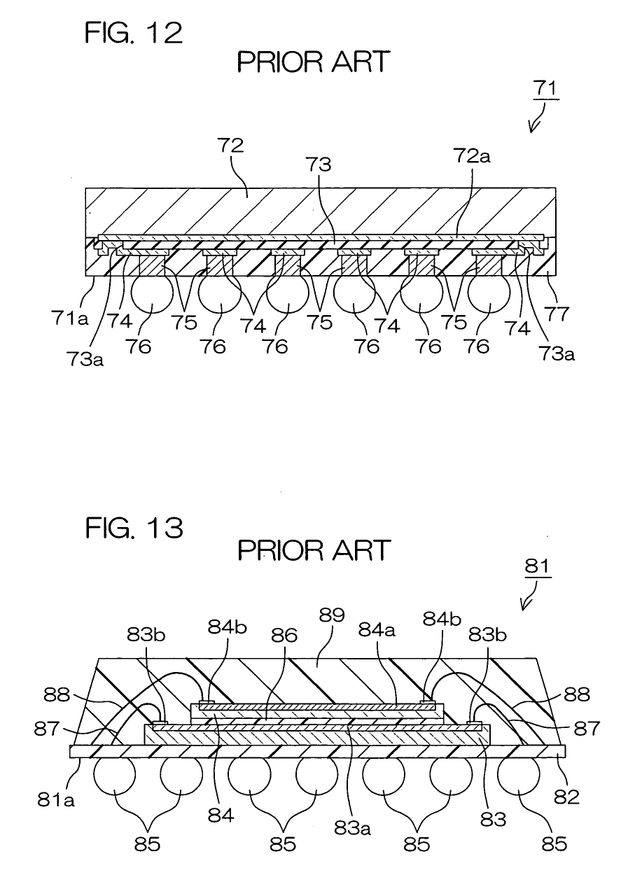

FIG. 11 is a schematic bottom view for explaining a production method for the semiconductor device 51. The semiconductor device 51 is produced from a semiconductor substrate formed with a plurality of semiconductor chips 2. In FIG. 11, a wafer W is shown as such a semiconductor substrate.

The wafer W has through-holes 56 provided in regions spanned between adjacent semiconductor chips 2 in the wafer W as seen perpendicularly to the wafer W. Electrically conductive films 57 electrically connected to functional elements 2a of the respective semiconductor chips 2 are provided on interior surfaces of the through-holes 56 and on a bottom surface 12B around the through-holes 56.

The electrically conductive films 57 are each provided across a boundary B (indicated by a one-dot-and-dash line in FIG. 11) between the adjacent semiconductor chips 2 as extending perpendicularly to the boundary B. The electrically conductive films 57 are formed, for example, by electrolytic plating. The through-holes 56 are not completely filled with the electrically conductive films 57, but each has a cylindrical hole inside the electrically conductive film 57 in the through-hole 56.

The semiconductor device 51 is produced by cutting the wafer W along the boundaries B between the adjacent semiconductor chips 2 by a dicing blade or a cutting die. The electrically conductive films 57 thus cut serve as the external connection terminals 52, and portions of the electrically conductive films 57 present on the interior surfaces of the through-holes 56 serve as the concave portions 54.

The through-holes 56 are not completely filled with the electrically conductive films 57. Therefore, this production method reduces abrasion of a tool such as the dicing blade or the cutting die to be used for cutting the wafer W along the boundaries between the adjacent semiconductor chips 2 as compared with the case where the wafer W formed with the columnar electrodes 17, 17A is cut (see FIGS. 3A and 3B).

While the embodiments of the present invention have thus been described, the present invention may be embodied in other ways. In the embodiments described above, the external connection terminals 10 are electrically connected to the electrodes of the functional element 2a via the rewirings 5, but external connection terminals each having surfaces exposed from the side surface 12S and the bottom surface 12B and electrically connected to none of the electrodes of the functional element 2a may be provided. Such external connection terminals also contribute to the bonding to the mounting board.

In the second embodiment, the heat-sink terminal 22 is not necessarily required to be electrically connected to the semiconductor chip 2.

The heat-sink terminal and the second semiconductor chip may be provided in a single semiconductor device. In this case, a heat-sink terminal (having a smaller size than the heat-sink terminal 22 shown in FIGS. 4 and 5) may be provided, for example, in a space between the second semiconductor chip 33 and the external connection terminals 10 in the semiconductor device 31 or 41 of FIG. 6 or 7.

While the present invention has been described in detail by way of the embodiments thereof, it should be understood that these embodiments are merely illustrative of the technical principles of the present invention but not limitative of the invention. The spirit and scope of the present invention are to be limited only by the appended claims.

This application corresponds to Japanese Patent Application No. 2004-300532 filed with the Japanese Patent Office on Oct. 14, 2004, the disclosure of which is incorporated herein by reference.

What is claimed is:

1. A semiconductor device comprising:
a first semiconductor chip having a first functional surface formed with a first functional element;
a protective resin layer provided on the first functional surface; and
an external connection terminal provided on a peripheral portion of the first functional surface for external electrical connection, the external connection terminal having a bottom surface exposed from a bottom surface of the protective resin layer facing away from the first functional surface and a side surface exposed from a side surface of the protective resin layer.

2. A semiconductor device as set forth in claim 1, further comprising a heat-sink terminal provided in a center region of the first functional surface located inwardly of the peripheral portion formed with the external connection terminal and having a surface exposed from the bottom surface of the protective resin layer.

3. A semiconductor device as set forth in claim 1, further comprising a second semiconductor chip having a second functional surface formed with a second functional element and connected to the first semiconductor chip with the second functional surface thereof being opposed to the first functional surface, the second semiconductor chip having a smaller size than the first semiconductor chip as seen in plan perpendicularly to the first functional surface.

4. A semiconductor device as set forth in claim 1, wherein
the protective resin layer has a concave recess provided in the side surface thereof, and
the external connection terminal includes a concave portion provided on an interior surface of the concave recess as having a shape conforming to an interior shape of the concave recess.

5. A semiconductor device as set forth in claim 1, wherein
the first semiconductor chip has a side surface which is substantially flush with the side surface of the protective resin layer.

6. A semiconductor device as set forth in claim 1, wherein
the external connection terminal includes a main portion embedded in the protective resin layer, and a coating film provided on a surface of the main portion as having the exposed bottom surface and the exposed side surface and composed of a material having a higher solder wettability than the main portion.
